(19) United States
(12) Patent Application Publication
(10) Pub. No.: US 2005/0280483 A1
(43) Pub. Date: Dec. 22, 2005

(54) Filter

(75) Inventor: Hsueh-Ming Shih, Taipei (TW)

Correspondence Address: BIRCH STEWART KOLASCH & BIRCH, PO BOX 747, FALLS CHURCH, VA, 22040-0747, US

(73) Assignees: Hsueh-Ming SHIH; TAK TECHNOLOGY CO., LTD.

(21) Appl. No.: 11/137,464

(22) Filed: May 26, 2005

Related U.S. Application Data
(63) Continuation-in-part of application No. 10/870,038, filed on Jun. 18, 2004.

(51) Int. Cl. H03H 7/01

(52) U.S. Cl. 333/181

(57) ABSTRACT

The current invention discloses a filter for large current applications. The filter comprises a metal frame including a rectangular member and a central, transverse shaft; a cylinder formed by two half cylindrical members around the shaft, the cylinder including a first winding space and a second winding space; a winding formed by coiling wire around the first and the second winding spaces; and a base including a top recess for receiving a bottom of the metal frame. The invention can increase winding space due to the unique design of the metal frame and the cylinder. Moreover, a simple winding is effected.

This application is a continuation-in-part, and claims priority, of from U.S. patent application Ser. No. 10/870,038 filed on Jun. 18, 2004, entitled “Wave filter assembly”.

### FIELD OF THE INVENTION

The present invention relates to filters and more particularly to such a filter particular suitable for large current applications.

### BACKGROUND OF THE INVENTION

Filters are widely employed in electrical or electronic devices (e.g., computers, TVs, sound reproducing products, etc.). Filters are responsible for preventing the passage of noise and eliminating EMI (electromagnetic interference). A conventional filter 1 is shown in FIGS. 1 and 2 and comprises a metal frame 10 having a section of n and including a transverse shaft 100, and two half cylinders 11 each including two half circular outer grooves 110, a half circular outer trough 111 provided on a wall separating the grooves 110, a toothed section 112 provided along one half circular end, and a half circular axial channel 113 in which both the half cylinders 11 are adapted to engage around the shaft 100 to form a complete cylinder. The filter 1 further comprises a rectangular base 12 including a central recess 120 for receiving the cylinder, two side cavities 121 formed by four corner posts for snugly receiving the sides of the metal frame 10, four pegs 122 extended downwardly from four bottom corners, and a plurality of peripheral longitudinal tunnels 123 (two are shown in either front or rear side). Either wire 13 may pass one tunnel 123 and exit the other tunnel 123 after winding the groove 110. Also, portions of either wire 13 below the tunnels 123 are secured to the pegs 122.

However, the prior art suffered from several disadvantages. For example, the forming of two windings is difficult and may undesirably consume precious time and labor. Also, the insulating outer shell of the wire 13 is subject to damage in the winding process, resulting in a short circuit. Further, the provision of two grooves 110 can occupy a large space, i.e., less space available for two windings of wire 13. As such, the prior filter 1 is simply suitable for small current applications. As a result, power of the filter 1 is relatively small. This prior design is low in industrial applicability. Therefore, it is desirable to provide an improved filter suitable for large current applications in order to overcome the above drawbacks of the prior art.

### SUMMARY OF THE INVENTION

It is an object of the present invention to provide a filter particular applicable for large current applications.

To achieve the above and other objects, the present invention provides a filter comprising a metal frame including a rectangular member and a central, transverse shaft; a cylinder formed by two half cylindrical members around the shaft, the cylinder including a first winding space and a second winding space; a winding formed by coiling wire around the first and the second winding spaces; and a base including a top recess for receiving a bottom of the metal frame. The present invention can increase winding space due to the unique design of the metal frame and the cylinder. Moreover, the present invention is particularly suitable for large current applications. Further, the present invention has a simple winding.

The above and other objects, features and advantages of the present invention will become apparent from the following detailed description taken with the accompanying drawings.

### BRIEF DESCRIPTION OF THE DRAWINGS

FIG. 1 is an exploded view of a conventional filter;

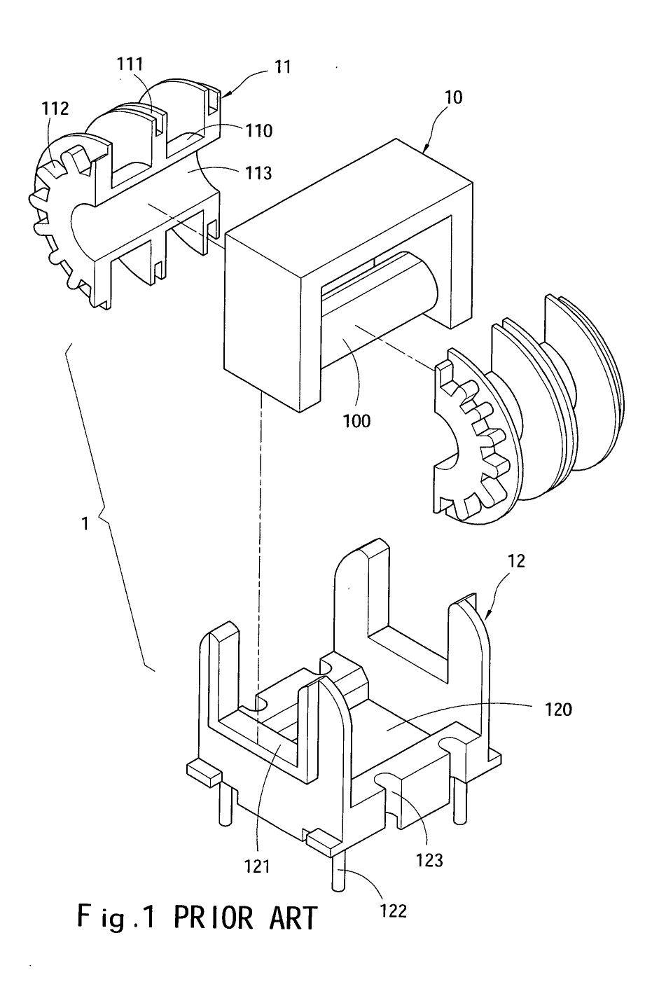

FIG. 2 is a perspective view of the assembled filter shown in FIG. 1;

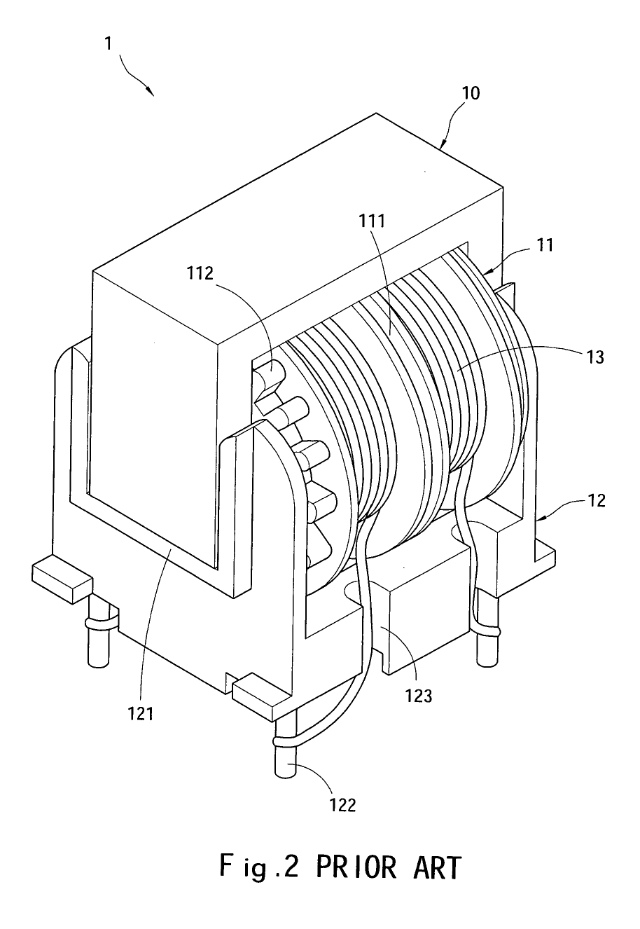

FIG. 3 is an exploded view of a preferred embodiment of filter according to the invention; and

FIG. 4 is a perspective view of the assembled filter shown in FIG. 3.

### DETAILED DESCRIPTION OF THE PREFERRED EMBODIMENTS

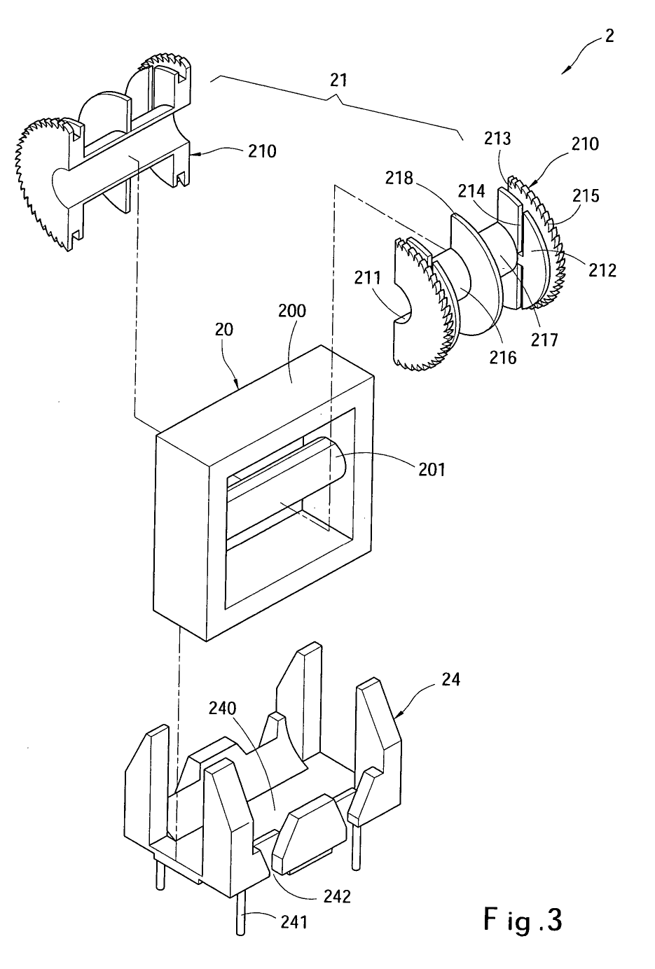

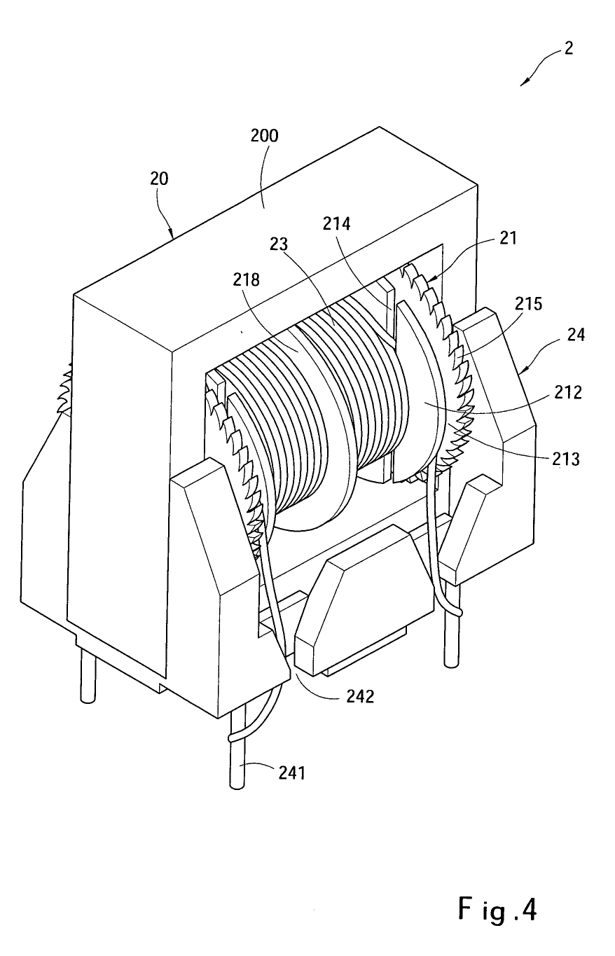

Referring to FIGS. 3 and 4, there is shown a filter 2 constructed in accordance with a preferred embodiment of the invention comprising a metal frame 20, a cylinder 21, a winding 23, and a base 24. Each component will be described in detailed below.

The metal frame 20 is implemented as a magnet and comprises a rectangular member 200 and a central, transverse shaft 201. The transverse cylinder 21 comprises two half cylindrical members 210 coupled around the shaft 201 of the metal frame 20. The cylinder 21 comprises an axial channel 211 sleeved on the shaft 201, an intermediate annular flange 218 provided on the shaft 201 for forming a first winding space 216 and a second winding space 217, and a pair of proximate first disc 212 and second disc 213 at either side in which the first disc 212 comprises a longitudinal slit 214 with the wire of the winding 23 passed. This configuration can facilitate winding and thus can decrease winding time. The second disc 213 comprises a circumferential toothed section 215 connected to a winding machine (not shown) in a winding process. The winding 23 is implemented as a flat wire having copper conductor or a conventional enameled wire. The winding 23 is wound on the first winding space 216 and the second winding space 217 sequentially. The rectangular base 24 includes a top recess 240 for receiving a bottom of the metal frame 20, four pegs 241 extended downwardly from four bottom corners, and two peripheral longitudinal tunnels 242 provided in either front or rear side. The portions of the winding 23 leaving the cylinder 21 are adapted to pass the tunnels 242 and be secured to the pegs 241 by, for example, soldering.

In view of the construction of the filter 2, it is seen that the cylinder 21 is adapted to sleeve on the shaft 201 of the metal frame 20, resulting in an increase of the winding space. This is because some portions of the second disc 213 are unoccupied (i.e., being available for use) due to the provision of the toothed section 215 on a circumference of the second disc 213. In this regard, wire of the winding 23 having a larger section can be used. Accordingly, the filter 2 formed by the winding 23 and other components can be applied to large current applications since the larger section of the winding 23 the larger of electric currents that pass the winding 23. Moreover, the provision of the slits 214 in the cylinder 21 effects a simple, ordered winding, resulting in a decrease of working time and labor. Further, in the case of the winding 23 formed by a flat wire having copper conductor, advantages including being aesthetic, applicable to large current and power applications due to larger section of the wire, reduction of the turns of winding, simple winding procedure, and low power loss can be obtained. Hence, the invention has a highly industrial applicability.

While the invention herein disclosed has been described by means of specific embodiments, numerous modifications and variations could be made thereto by those skilled in the art without departing from the scope and spirit of the invention set forth in the claims.

1. A filter for large current applications, comprising:
a metal frame including a rectangular member and a central, transverse shaft;
a cylinder formed by two half cylindrical members around the shaft and the cylinder including a first winding space and a second winding space;
a winding formed by coiling wire around the first and the second winding spaces; and
a base including a top recess for receiving a bottom of the metal frame.

2. The filter of claim 1, wherein the cylinder further comprises an intermediate annular flange provided on the shaft for separating the first winding space from the second winding space.

3. The filter of claim 1, wherein the cylinder further comprises a pair of proximate first disc and second disc at either side, the first disc including a longitudinal slit with the wire of the winding passed so as to facilitate winding and decrease winding time, and the second disc including a circumferential toothed section connected to a winding machine for winding.

4. The filter of claim 1, wherein the winding is a flat wire having copper conductor.

5. The filter of claim 1, further comprising the winding is an enameled wire.

6. The filter of claim 1, wherein the base further comprises a plurality of pegs extended downwardly and a plurality of peripheral longitudinal tunnels so that portions of the winding leaving the cylinder are adapted to pass the tunnels and be secured to the pegs.
